(19) United States
(12) Patent Application Publication
(10) Pub. No.: US 2023/0377883 A1
(43) Pub. Date: Nov. 23, 2023

(54) SYSTEM AND METHOD FOR DIRECTED SELF-ASSEMBLY WITH HIGH BOILING POINT SOLVENT

(71) Applicant: Taiwan Semiconductor Manufacturing Co., Ltd., Hsinchu (TW)

(72) Inventors: Yu-Ling CHANG CHIEN, Hsinchu (TW); Yu-Chung SU, Hsinchu (TW); Yahru CHENG, Hsinchu (TW); Ching-Yu CHANG, Hsinchu (TW); Chin-Hsiang LIN, Hsinchu (TW)

(21) Appl. No.: 17/750,148

(22) Filed: May 20, 2022

(51) Int. Cl. H01L 21/027

(52) U.S. Cl. CPC H01L 21/0271

(57) ABSTRACT

A system and method utilize directed self-assembly films, including block copolymers and solvents, to form features on a wafer. The solvents have high boiling points. The high boiling points of the solvents enable directed self-assembly processes to utilize very high temperature, rapid thermal annealing processes to generate a pattern of first and second polymer structures over a wafer from the directed self-assembly films. The pattern of the first and second polymer structures can be utilized to form the features on the wafer.

### BACKGROUND

There has been a continuous demand for increasing computing power in electronic devices including smart phones, tablets, desktop computers, laptop computers and many other kinds of electronic devices. Integrated circuits provide the computing power for these electronic devices. One way to increase computing power in integrated circuits is to increase the number of transistors and other integrated circuit features that can be included for a given area of a semiconductor substrate.

The features in an integrated circuit are produced, in part, with the aid of photolithography. Traditional photolithography techniques include generating a mask outlining the pattern of features to be formed on an integrated circuit die. The photolithography light source irradiates the integrated circuit die through the mask. The size of the features that can be produced via photolithography of the integrated circuit die is limited, in part, on the lower end, by the wavelength of light produced by the photolithography light source. Smaller wavelengths of light can produce smaller feature sizes.

Extreme ultraviolet (EUV) light is used to produce particularly small features due to the relatively short wavelength of EUV light. However, when using EUV to pattern photoresist for features having very small pitches, there can be problems. For example, a stochastic effect of the EUV irradiation may cause uneven edges and surfaces in photoresist features after patterning. These distortions may then be transferred to integrated circuit features, resulting in poorly functioning or non-functioning circuits.

### BRIEF DESCRIPTION OF THE DRAWINGS

FIG. 1 is a flow diagram of a process for forming features on a wafer, in accordance with some embodiments.

FIGS. 2A-2C are top views of a directed self-assembly film, in accordance with some embodiments.

FIGS. 3A-3C are top views of a directed self-assembly film.

FIG. 4 illustrates high boiling point solvents, in accordance with some embodiments.

FIGS. 5A-5P are cross-sectional and perspective views of a wafer at various stages of processing, in accordance with some embodiments.

FIGS. 6A-6M are cross-sectional, perspective, and top views of a wafer at various stages of processing, in accordance with some embodiments.

FIG. 7 is a block diagram of a wafer processing system, in accordance with some embodiments.

FIGS. 8 and 9 are flow diagrams of methods for forming features on a wafer, in accordance with some embodiments.

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In the following description, certain specific details are set forth in order to provide a thorough understanding of various embodiments of the disclosure. However, one skilled in the art will understand that the disclosure may be practiced without these specific details. In other instances, well-known structures associated with electronic components and fabrication techniques have not been described in detail to avoid unnecessarily obscuring the descriptions of the embodiments of the present disclosure.

Unless the context requires otherwise, throughout the specification and claims that follow, the word “comprise” and variations thereof, such as “comprises” and “comprising,” are to be construed in an open, inclusive sense, that is, as “including, but not limited to.”

The use of ordinals such as first, second and third does not necessarily imply a ranked sense of order, but rather may only distinguish between multiple instances of an act or structure.

Reference throughout this specification to “some embodiments” or “an embodiment” means that a particular feature, structure or characteristic described in connection with the embodiment is included in at least some embodiments. Thus, the appearances of the phrases “in some embodiments” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its sense including “and/or” unless the content clearly dictates otherwise.

Embodiments of the present disclosure utilize novel directed self-assembly processes to provide reliable feature formation on wafers in significantly reduced amounts of time. Embodiments of the present disclosure utilize block copolymers in conjunction with high boiling point solvents for rapid directed self-assembly processes. Because the directed self-assembly processes use high boiling point solvents, annealing processes can be performed at higher temperatures and for significantly reduced lengths of time while producing patterned morphologies from the block copolymers with very small pitches. The result is that small pitch features are formed effectively and efficiently. This further results in faster overall processing for semiconductor wafers, integrated circuits with higher performances, and better overall yields.

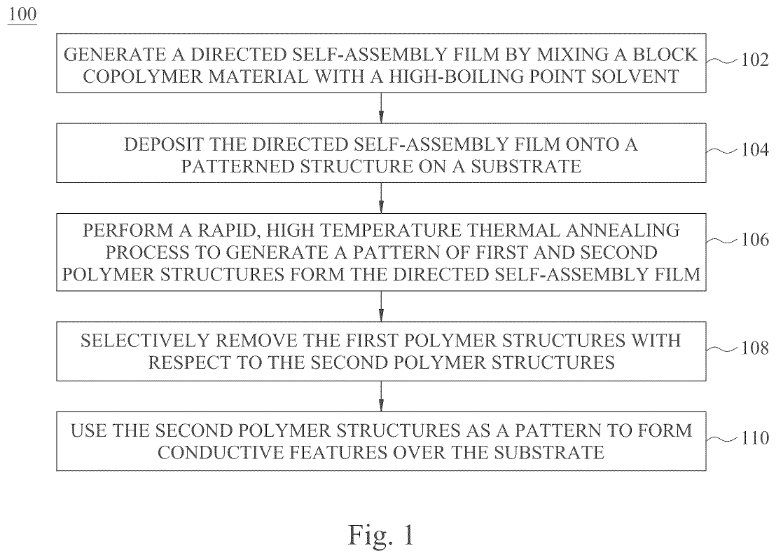

FIG. 1 is a flow diagram of a process 100 for forming small pitch features on semiconductor wafers, according to some embodiments. The process 100 utilizes block copolymer materials and directed self-assembly processes to form patterns that can be utilized to form small pitch features on the semiconductor wafers. As will be set forth in more detail below, the process 100 utilizes high boiling point solvents and high-temperature annealing processes to rapidly perform the directed self-assembly processes.

At 102, the process 100 generates a directed self-assembly film. The directed self-assembly film includes a block copolymer material. In some embodiments, the block copolymer includes two different homopolymer subunits. A copolymer with two different homopolymer subunits may be termed a diblock polymer. In the initial mixture, the two homopolymer subunits are linked together by a covalent bond.

The block copolymer material may be made up of blocks of different polymerized monomers. The different polymerized monomers should exhibit good etching selectivity such that when the block copolymer material is self-assembled, one of the polymerized monomers can be etched while the other polymerized monomer is not etched. In one example, the block copolymer material includes polystyrene-b-poly(methyl methacrylate) referred to as PS-b-PMMA herein. This material may be formed by first polymerizing styrene to form polystyrene (PS). Afterwards, the PMMA is formed by polymerizing metal methacrylate (MMA) from the reactive end of the polystyrene chains to form polymethyl methacrylate (PMMA). Polystyrene-b-poly(dimethylsiloxane), referred to herein as PS-b-PDMS, is another example of a diblock copolymer that can be utilized in the process 100. Embodiments of the present disclosure are not limited to the aforementioned diblock polymers. Other diblock copolymer materials can be utilized without departing from the scope of the present disclosure.

In some embodiments, copolymer materials other than diblock copolymer materials can be utilized. For example, triblock copolymer materials can be utilized in accordance with principles of the present disclosure. A triblock copolymer includes three different chemical blocks. Copolymers including more than three chemical blocks can be utilized without departing from the scope of the present disclosure.

Generating the directed self-assembly film includes mixing a solvent with the block copolymer material. The solvent increases the mobility of the blocks of the copolymer material in the solvent. This can enable the copolymer material to more readily assemble into a well-ordered pattern, based on a pattern of an underlying structure, as will be described in more detail below. The solvent may have different solvating properties relative to the different polymer blocks of the block copolymer. Alternatively, the solvent may have the same solvating properties relative to the different polymer blocks.

In some embodiments, the solvent includes multiple individual solvents. For example, the solvent may include a first solvent with a high solubility for one of the polymer blocks. The solvent may also include a second solvent with high solubility for the other of the polymer blocks. The solvent may be formed by mixing the first and second solvents together. The solvent may then be added to the copolymer material.

A thermal annealing process with a temperature greater than Tg, where Tg is the glass transition temperature, can enhance the mobility of the blocks during the directed self-assembly process. The combination of the solvent action and the thermal annealing process can result in very rapid directed self-assembly processes in which the copolymer material forms first and second polymer structures in a desired pattern.

If the boiling point of the solvent is low, then it is possible that the solvent will evaporate too quickly during the thermal annealing process. If this occurs, direct self-assembly would trigger only by high annealing temperature (>Tg) and may need a duration of 2.5 hr to form well-ordered morphology of the first and second polymer materials. Short annealing times (<5 min) for the directed self-assembly process may result in a poorly ordered morphology without a desired pattern for forming features on the semiconductor wafer.

Thus, both the overall time and cost of producing semiconductor wafers are made larger by only thermal annealing processes without remaining solvent as part of the directed self-assembly processes.

Advantageously, the process 100 utilizes a high boiling point solvent. In one example, the solvent has a boiling point that is greater than 180° C. Such a high boiling point solvent enables the use of higher temperatures during the thermal annealing processes. Due to the high boiling point of the solvent, less solvent is evaporated during the high temperature thermal annealing process as compared to when a lower boiling point solvent is utilized. The combination of the remaining solvent and the high temperature of the annealing process results in rapid directed self-assembly processes that form well-ordered morphologies of first and second polymer materials.

In some embodiments, the solvent has a boiling point between 180° C. and 350° C. Temperatures in this range can enable high temperature thermal annealing processes that result in well-ordered morphologies in a relatively short amount of time. Further details regarding the thermal annealing processes are provided below. Embodiments in accordance with the present invention are not limited to solvents that include boiling points within the foregoing range. Solvents having boiling points falling outside the foregoing ranges can be used provided they increase the ability of the block copolymer to self-assemble at the selected annealing temperature.

In some embodiments, the solvent can include one or more of tripropylene glycol monomethyl ether (TPM, boiling point 243° C.), 2-phenoxyethanol (boiling point 245° C.), or heptyl ether (boiling point 262° C.). In some embodiments, the solvent can include one or more of dodecane (boiling point 216° C.), N,N′-dimethylpropyleneurea (DMPU, boiling point 246° C.), or 1,3-dimethyl-2-imidazolidinone (DMI, boiling point 225° C.). Other solvents which are able to affect the mobility of the block copolymer to the same degree as the foregoing solvents when the block copolymer and solvent are annealed can be utilized without departing from the scope of the present disclosure.

In some embodiments, a neutral high boiling point solvent is selected having a relative energy difference less than 1 for each block of the copolymer material. This relative energy difference can help control the volume ratio of each component of the copolymer material when it self-assembles. A neutral solvent can be either a single solvent or a blend of multiple solvents. The relative energy difference (RED) can be calculated as RED=Ra/R₀, where R₀ is the interaction radius of the polymer and the solvent and Ra is the distance between Hansen parameters (δ_{d}, δₚ, and δₕ). It is beneficial if the solvent has a RED <1 for each block of a copolymer material. R₀ can be determined experimentally for a solvent and a polymer. If δ_{d} is the energy from dispersion forces between molecules, δₚ is the energy from dipolar intermolecular forces between molecules, and & is the energy from hydrogen bonds between molecules, then Ra can be found by the following relationship:

(Ra)²=4(δ_{d2}−δ_{d1})²+(δₚ₂−δₚ₁)²+(δₕ₂−δₕ₁)²

At 104, the process 100 includes depositing a directed self-assembly film onto a patterned structure on a substrate. In particular, the directed self-assembly material 102 can be deposited onto a patterned structure. The directed self-assembly material can be deposited in liquid form by a spin-on process. Alternatively, the directed self-assembly material can be deposited by other processes without departing from the scope of the present disclosure.

While the process 100 of FIG. 1 indicates that the solvent is mixed with the block copolymer material prior to deposition on the patterned structure, in practice, the block copolymer material can be exposed to the solvent after the block copolymer material has been deposited on the patterned structure. Other processes for exposing the block copolymer material to the solvent can be utilized without departing from the scope of the present disclosure.

The substrate can include a semiconductor layer of a wafer. Alternatively, the substrate can include a dielectric layer, a conductive layer, or other types of layers. The patterned structure can include one or more layers formed on the substrate with a particular pattern.

In some embodiments, the patterned structure can include a first layer having a substantially flat top surface and pattern of ridges, spacers, or other raised features formed from a second layer on the top surface of the first layer. Parts of the top surface of the first layer are exposed by the pattern formed from the second layer. The material of the first layer may be more hydrophobic or hydrophilic than the material of the second layer. This can help ensure that during the directed self-assembly process, the first and second polymer materials will assemble in a pattern based on the patterned structure. Accordingly, the self-assembly film can be deposited on the patterned structure so that a pattern of first and second polymer materials may be formed via the directed self-assembly process, as will be described in further detail below.

In some embodiments, the patterned structure can include a single layer of material over the substrate. The single-layer of material may include an organic polymer or other dielectric material that has been exposed, via a mask of photoresist, to irradiation. The irradiation causes a chemical change in the exposed portions of the organic polymer. The result is a patterned structure having a relatively flat top surface. The pattern corresponds to the pattern of the exposed portions of the organic material that have undergone the chemical change. The chemically changed portions and unchanged portions can have different hydrophobic or hydrophilic properties such that the copolymer material will self-assemble into a pattern of first and second polymer structures based on the pattern of changed and unchanged portions of the patterned structure. Other types of patterned structures can be utilized without departing from the scope of the present disclosure.

At 106, the process 100 includes performing a rapid high temperature thermal annealing process. The rapid high temperature thermal annealing process causes the block copolymer material of the directed self-assembly film to self-assemble into first and second polymer structures in a pattern based on the pattern of the underlying structure.

In some embodiments, the high temperature thermal annealing process is performed at a temperature between 200° C. and 350° C. This range of temperatures can result in rapid self-assembly of the first and second polymer structures. Due to the high boiling point of the solvent, the temperature of the annealing process does cause the solvent to rapidly evaporate before self-assembly is complete. In some embodiments, the solvent has a boiling point that is less than the temperature of the thermal annealing process. In these cases, even though the temperature of the thermal annealing process is higher than the boiling point of the solvent, because the boiling point of the solvent is relatively high, the period of the annealing process can be controlled so the solvent does not evaporate entirely before directed self-assembly is complete. Accordingly, the temperature of the thermal annealing process can be selected to be higher than the boiling point of the selected solvent. In some embodiments, the thermal annealing process is performed at a temperature greater than 250° C. or greater than 350° C. Such a high temperature may further shorten the duration of the thermal annealing process while providing well-ordered morphologies of the self-assembled film. Other temperature ranges for the annealing process can be utilized without departing from the scope of the present disclosure.

In some embodiments, the temperature of the annealing process is lower than the boiling point of the solvent. In these cases, the solvent will not evaporate before the directed self-assembly process is complete.

In some embodiments, the thermal annealing process has a duration between 60 seconds and 300 seconds. Durations within this range may be sufficient to ensure that the directed self-assembly process is completed and a well-ordered morphology of the first and second polymer structures has been formed. The length of the thermal annealing process in accordance with embodiments of the present disclosure is short compared to other possible annealing processes that utilize lower temperature and lower boiling point solvents. Such other low temperature, low boiling point solutions may take up to two hours in length in order to produce a well-ordered morphology of the first and second polymer structures. Accordingly, a high temperature thermal annealing process using a high boiling point solvent and a duration, as described above, produces self-assembled films quickly and effectively, thereby increasing the throughput of the manufacturing process.

At 108, the process 100 selectively removes the first polymer structures with respect to the second polymer structures. Accordingly, the block copolymers are selected so that the resulting first and second polymer structures are selectively etchable relative to each other. Accordingly, at 108, an etching process is performed that selectively removes the first polymer structures with respect to the second polymer structures. This exposes underlying materials in a pattern of the removed first polymer structures.

At 110, the process 100 includes using the second polymer structures as a pattern to form features over the substrate. In some embodiments, the features are conductive features such as metal lines or conductive vias, though other types of features can be formed without departing from the scope of the present disclosure.

In some embodiments, operation 110 can include using the second polymer structures as a mask to etch trenches in one or more layers below the second polymer structures and above the substrate. The one or more layers can include the patterned structure, one or more hard mask layers, or other types of layers. After the trenches have been formed, a conductive material can be deposited over the substrate in the trenches. In the case of metal lines, the intervening materials may be removed, leaving the metal lines on the substrate. Interlevel dielectric layers can be deposited on the metal lines. In the case of conductive vias, the trenches may correspond to apertures that contact a metal line or other conductive feature in or on the substrate. Depositing the conductive material forms the conductive vias or plugs in the apertures. Other types of features can be formed without departing from the scope of the present disclosure.

In some embodiments, operation 110 can include forming spacers in the gaps left by the removal of the first polymer structures. The second polymer structures can then be removed. The spacers can then be used as a mask or pattern to etch trenches and to form metal lines, conductive vias, or other features as described above. The pattern formed by removal of the first polymer structures can be utilized in various other ways to form features over the substrate without departing from the scope of the present disclosure.

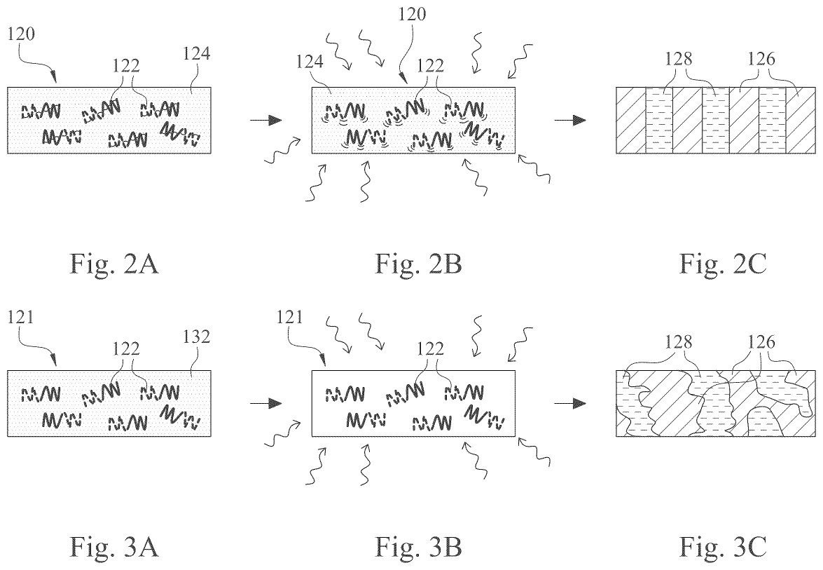

FIG. 2A is a simplified top view of a directed self-assembly film 120 formed over a substrate (not shown), according to one embodiment. The directed self-assembly material includes a block copolymer material 122 and a solvent 124. The block copolymer material 122 corresponds to the copolymer material described in relation to FIG. 1. The solvent 124 corresponds to the solvent described in relation to FIG. 1. The directed self-assembly film 120 can be deposited on a substrate as described in relation to FIG. 1.

In FIG. 2B, a thermal annealing process is performed on the directed self-assembly film 120. The thermal annealing process can be performed at a temperature and duration as described in relation to FIG. 1. Because the solvent 124 is a high boiling point solvent, the solvent is not quickly evaporated and remains to facilitate the directed self-assembly process. The solvent may evaporate as the directed self-assembly process is completed.

In FIG. 2C, the directed self-assembly process is complete. The copolymer material 122 has formed into first polymer structures 126 and second polymer structures 128. The first polymer structures 126 and the second polymer structures 128 are in a well-ordered pattern of alternating stripes corresponding to the different polymer components of the copolymer material 122. After the structure shown in FIG. 2C has been attained, either the first polymer structures 126 or the second polymer structures 128 can be selectively removed to expose structures and layers below. The remaining first or second polymer structures can be used as a mask to etch trenches and form features above the substrate, as described in relation to FIG. 1.

FIGS. 3A-3C are top views of a directed self-assembly film 121. The directed self-assembly film 121 includes a copolymer material 122 and a low boiling point solvent 132. The low boiling point solvent 132 has a boiling point that is lower than the boiling point of the solvent 124 of FIGS. 2A-2C. Accordingly, in FIG. 3B, when a high temperature thermal annealing process is performed, the solvent 132 has evaporated prior to the annealing process or evaporates before the high temperature annealing process is completed. Because the solvent 132 is not present or present at a reduced amount, during the thermal annealing process, mobility of the copolymers 122 is reduced. The result is that after the thermal annealing process, the first and second polymer structures 126 and 128 are not in a well-ordered morphology. Thus, the first and second polymer structures 126 and 128 of FIG. 3C cannot be used to reliably form features on the substrate. Accordingly, using a high boiling point solvent 124 as described in relation to FIGS. 2A-2C enables the reliable use of high temperature thermal annealing processes with resulting well-ordered morphologies of first and second polymer structures in shorter periods of time. Using a high temperature thermal annealing process without high boiling point solvents, results in the disordered morphologies shown in FIG. 3C.

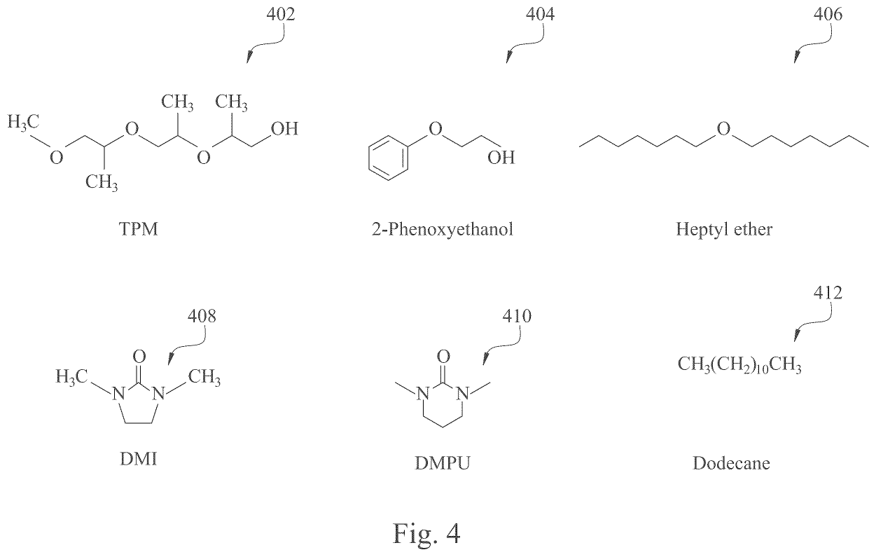

FIG. 4 illustrates a plurality of high temperature solvents, in accordance with some embodiments. The solvent 402 is tripropylene glycol monomethyl ether (TPM) with a boiling point of 243° C. The solvent 404 is 2-phenoxyethanol with a boiling point of 245° C. The solvent 406 is heptyl ether with a boiling point of 262° C. The solvent 408 is 1,3-dimethyl-2-imidazolidinone (DMI) with a boiling point of 225° C. The solvent 410 is N,N′-dimethylpropyleneurea (DMPU) with a boiling point of 246° C. The solvent 412 is dodecane with a boiling point of 216° C. Embodiments in accordance with the present disclosure are not limited to the foregoing solvents. Other solvents with boiling points similar to the solvents described above which are able to mix with the block copolymers described above and maintain the mobility of the block copolymers during an annealing process are within the scope of the present disclosure.

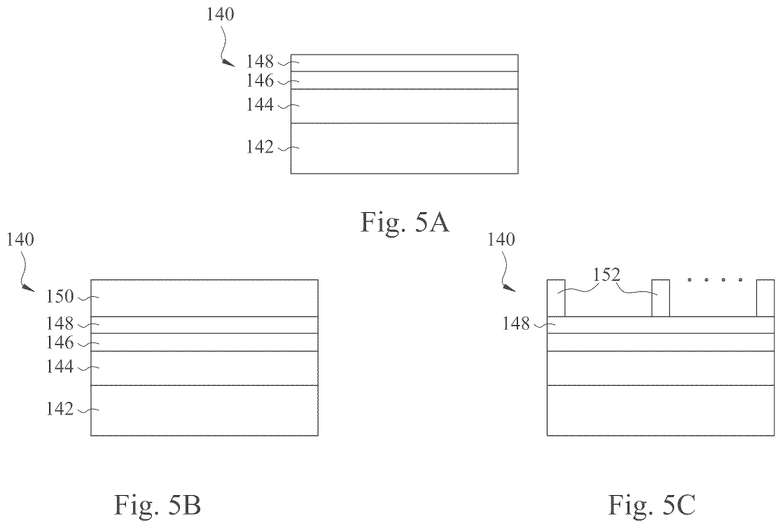

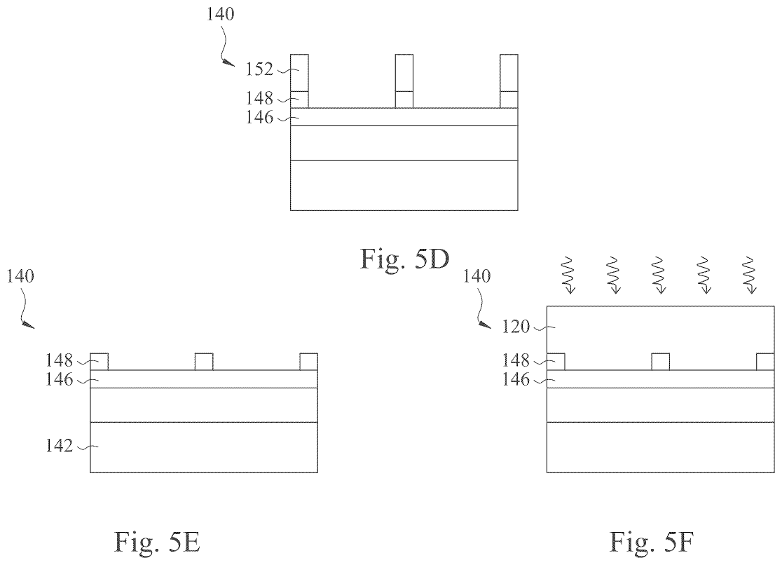

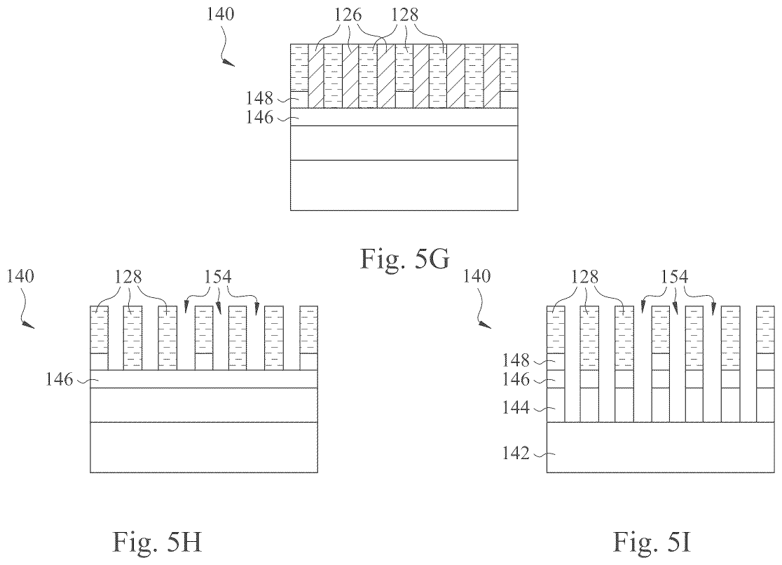

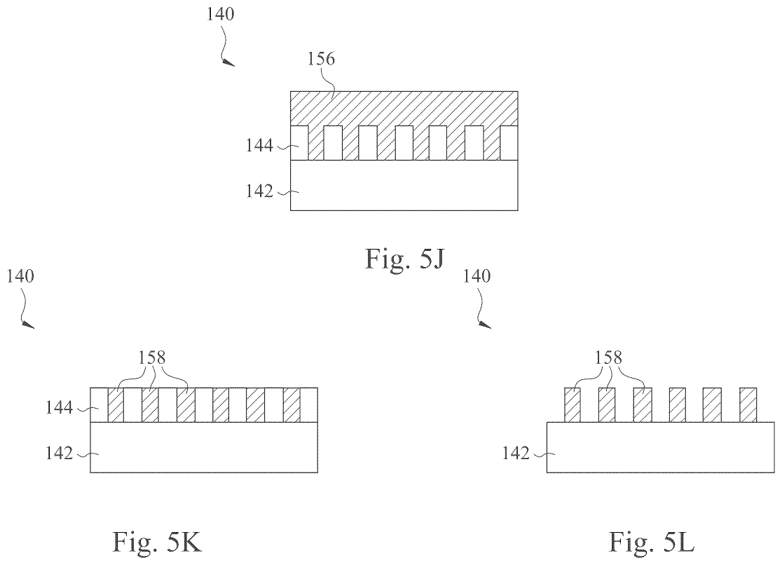

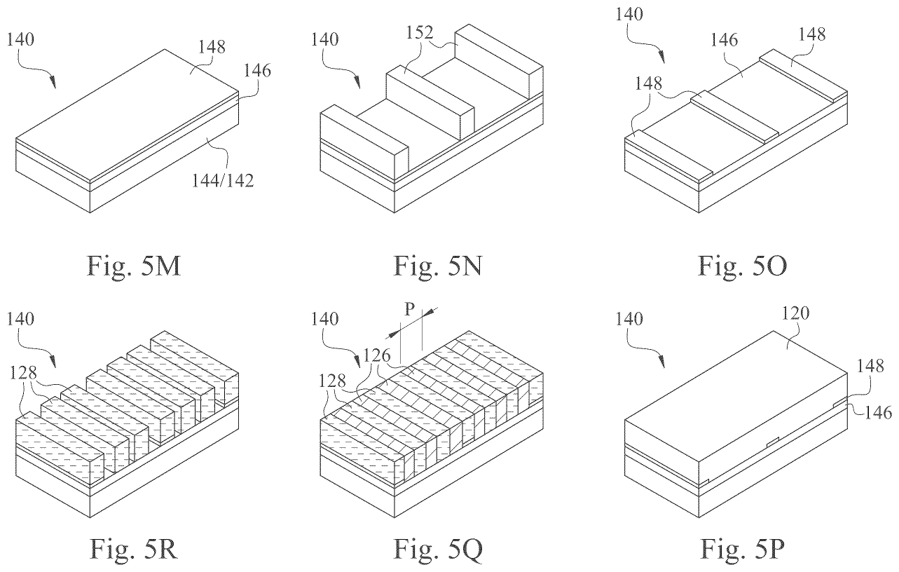

FIGS. 5A-5L are cross-sectional views of a wafer 140 at various stages of processing, in accordance with some embodiments. With reference to FIG. 5A, a wafer 140 includes a substrate 142. The substrate 142 can include a semiconductor material such as silicon, silicon germanium, or another semiconductor material. Alternatively, the substrate 142 can include a dielectric material such as silicon dioxide, silicon carbide, or other dielectric materials. Alternatively, the substrate 142 can include a conductive material such as copper, aluminum, titanium, tungsten, or other conductive materials. The process shown in relation to FIGS. 5A-5L utilizes directed self-assembly processes to form features on the substrate 142.

The wafer 140 includes a hard mask layer 144 on the substrate 142. The hard mask layer 144 may include a conductive material such as ruthenium, titanium nitride, or other conductive materials. Alternatively, the hard mask layer 144 may include a dielectric material such as silicon dioxide, silicon nitride, silicon carbide, or other dielectric materials. The thickness of the hard mask layer 144 may be between 5 nm and 100 nm. Other materials and thicknesses can be utilized for the hard mask layer 144 without departing from the scope of the present disclosure.

The wafer 140 includes a layer 146 on the hard mask layer 144. The layer 146 may include a dielectric material such as silicon oxide, silicon nitride, tetraethyl orthosilicate (TEOS), silicon oxynitride, an organic dielectric material, or other types of dielectric material. Alternatively, the layer 146 may include a semiconductor material or a conductive material. The layer 146 may have a thickness between 5 nm and 100 nm. Other materials and thicknesses can be utilized for the layer 146 without departing from the scope of the present disclosure.

The wafer 140 includes a layer 148 on the layer 146. The layer 148 includes a material that is selectively etchable with respect to the layer 146. Accordingly, the material of the layer 148 is different than the material of the layer 146, in some embodiments. The layer 148 may include a dielectric material such as silicon oxide, silicon nitride, tetraethyl orthosilicate (TEOS), silicon oxynitride, an organic dielectric material, or other types of dielectric material. Alternatively, the layer 148 may include a semiconductor material or a conductive material. The layer 148 may have a thickness between 1 nm and 100 nm. Other materials and thicknesses can be utilized for the layer 148 without departing from the scope of the present disclosure.

In FIG. 5B, a layer of photoresist 150 has been deposited on the layer 148. The layer of photoresist 150 can be deposited by a spin-on process or another type of process. The layer of photoresist 150 can include a positive photoresist or a negative photoresist.

In FIG. 5C, a photolithography process has been performed on the layer of photoresist 150. In some embodiments, a 193 nm immersion lithography process has been performed on the layer photoresist 150. In particular, the layer of photoresist 150 is irradiated via a mask and chemically changed portions of the layer of photoresist 150 have been removed to leave photoresist structures 152 in accordance with the mask pattern. Other types of photolithography processes can be performed without departing from the scope of the present disclosure. In some embodiments, the pitch of the photoresist structures 152 is between 30 nm and 100 nm, though other pitches can be utilized without departing from the scope of the present disclosure.

In FIG. 5D, an anisotropic etching process has been performed. The anisotropic etching process selectively etches the material of the layer 148 with respect to the material of the layer 146. The result is that the layer 148 is removed at all locations except where covered by a photoresist structure 152. The layer 146 is not substantially etched.

In FIG. 5E, the photoresist structures 152 have been removed. Removal of the photoresist structures 152 can be accomplished with an etching process that selectively etches the photoresist structures 152 with respect to the layer 148 and the layer 146. Collectively, the layer 146 and the remaining portions of the layer 148 form a patterned structure above the substrate 142. The pattern of the patterned structure corresponds to the positions of the remaining portions of the layer 148 on the layer 146.

In FIG. 5F, a directed self-assembly film 120 has been deposited on the patterned structure. In particular, the directed self-assembly film 120 has been deposited on the remaining portions of the layer 148 and the exposed portions of layer 146. In the process shown in FIG. 5F, the directed self-assembly film includes a diblock copolymer material and a solvent. In other embodiments, the copolymer material can be a triblock copolymer material or other number of blocks. In one example, the diblock copolymer material includes PS-b-PMMA, though other copolymer materials can be utilized without departing from the scope of the present disclosure. The solvent is a high boiling point solvent, as described in relation to FIGS. 1-4. The solvent can include one of the solvents shown in FIG. 4, or another suitable high boiling point solvent. The directed self-assembly film 120 can be deposited via a spin-on process, or via another process.

In some embodiments, the solvent is mixed with the copolymer material prior to depositing the directed self-assembly film 120 on the wafer 140. Alternatively, the copolymer material can be deposited on the wafer 140, followed by exposing the copolymer material to the solvent. Various processes for forming the directed self-assembly film 120 can be utilized without departing from the scope of the present disclosure.

In FIG. 5F, a rapid thermal annealing process is performed. The rapid thermal annealing process can be performed at a temperature between 200° C. and 350° C., as described previously in relation to FIG. 1. The rapid thermal annealing process can have a duration between 60 seconds and 300 seconds, as described previously in relation to FIG. 1. Other temperatures and durations can be utilized without departing from the scope of the present disclosure.

In FIG. 5G, first polymer structures 126 and second polymer structures 128 have been formed from the directed self-assembly film 120. In particular, performing the rapid high temperature annealing process with the high boiling point solvent has resulted in a well-ordered pattern of alternating stripes or blocks of the first polymer structures 126 and the second polymer structures 128. In some embodiments, the first polymer structures 126 are PMMA and the second polymer structures 128 are PS, though other polymer materials can be utilized without departing from the scope of the present disclosure.

The pattern of the first polymer structures 126 and second polymer structures 128 is based on the pattern of the remaining portions of the layer 148 on the layer 146. In particular, the polymer material of the second polymer structures 128 selectively assembles on the top surfaces of the remaining portions of the layer 148. This can be the result of the material of the layer 148 being more hydrophobic or more hydrophilic than the material of the layer 146. The polymer material of the second polymer structures 128 selectively form on the hydrophobic or hydrophilic top surface of the layer 148. The polymer material of the first polymer structures 126 forms adjacent to the second polymer structures 128 and has a similar width as the second polymer structures 128. Second polymer structures 128 form on the surface of the layer 146 adjacent to the first polymer structures 126. The result is the alternating pattern of the first and second polymer structures as shown in FIG. 5G. The pitch of the second polymer structures 128 may be between 10 nm and 50 nm, though other pitches can be utilized without departing from the scope of the present disclosure.

In FIG. 5H, an etching process has been performed. The etching process selectively removes the first polymer structures 126 with respect to the second polymer structures 128. The effect is to form trenches 154 between the remaining polymer structures 128. Portions of the top surface of the layer 146 are exposed in the trenches 154. The second polymer structures 128 are not substantially etched.

In FIG. 5I, an etching process has been performed. The etching process selectively etches the material of the layer 146 and the hard mask layer 144 with respect to the substrate 142. The result is that the trenches 154 extend through the hard mask layer 144 to the surface of the substrate 142. The etching process of FIG. 5I can include a single etching process or multiple etching processes.

In FIG. 5J, one or more etching processes have been performed to remove the second polymer structures 128, and the remaining portions of the layers 148 and 146. A conductive material 156 has been deposited on the exposed portions of the substrate 142 and the remaining portions of the hard mask layer 144. The conductive material 156 can be deposited by physical vapor deposition (PVD), chemical vapor deposition (CVD), atomic layer deposition (ALD), or by another deposition process. The conductive material 156 can include aluminum, copper, tungsten, titanium, gold, tantalum, or other conductive materials.

In FIG. 5K, a planarization process has been performed. The planarization process planarizes the top surface of the conductive material 156 with the top surface of the hard mask layer 144. The planarization process can include a chemical mechanical planarization (CMP) process, or another type of planarization process. The result is that metal lines 158 are formed on the substrate 142. The metal lines can correspond to conductive signal lines of an integrated circuit. The metal lines 158 can correspond to metal lines of a metal 0, metal 1, or metal interconnect layer of an integrated circuit. Alternatively, the process shown in FIG. 5K can be utilized to form conductive vias or plugs that can connect to other structures. The metal lines have a pitch based on the pitch of the first polymer structures 126.

In FIG. 5L, the hard mask layer 144 has been removed via an etching process. Subsequently, dielectric layers, such as an interlevel dielectric layer or other dielectric layers, can be formed on the substrate 142 covering the metal lines 158. In subsequent processes, conductive vias can be formed to contact the metal lines 158.

FIGS. 5M-5R are perspective views of the wafer 140 of FIGS. 5A-5L, according to some embodiments. FIG. 5M corresponds to a perspective view of the wafer 140 at the stage of processing of FIG. 5A. In FIG. 5M, the substrate 142 and the hard mask layer 144 are shown as a single layer. FIG. 5N is a perspective view of the wafer 140 at the stage of processing shown in FIG. 5C. FIG. 5O is a perspective view of the wafer 140 at the stage of processing corresponding to FIG. 5E. FIG. 5P is a perspective view of the wafer 140 at the stage of processing corresponding to FIG. 5F. FIG. 5Q is a perspective view of the wafer 140 at the stage of processing corresponding to FIG. 5G. FIG. 5Q illustrates the pitch of the first and second polymer structures 126 and 128. FIG. 5R is a perspective view of the wafer 140 at the stage of processing corresponding to FIG. 5H.

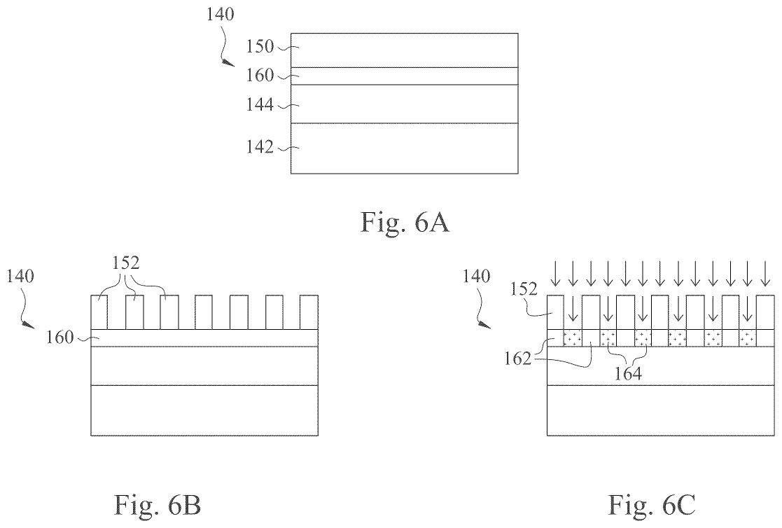

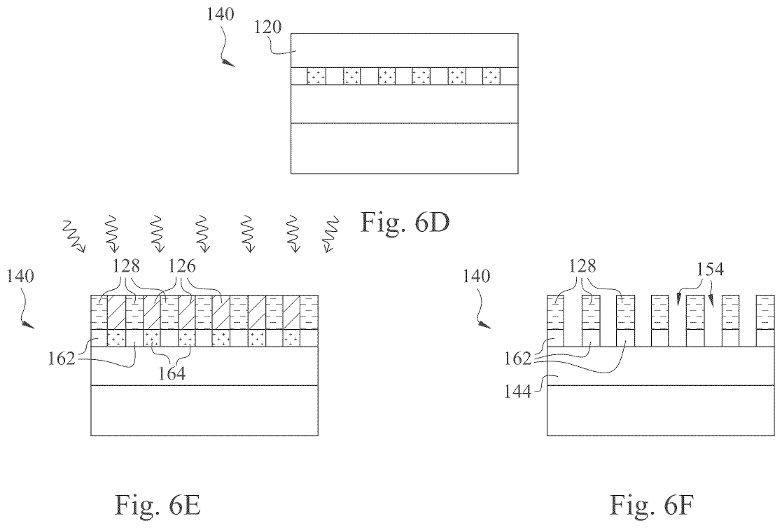

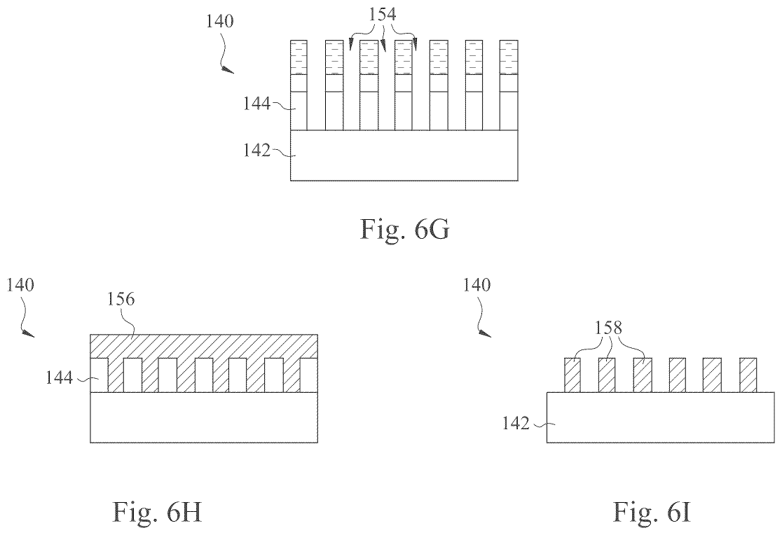

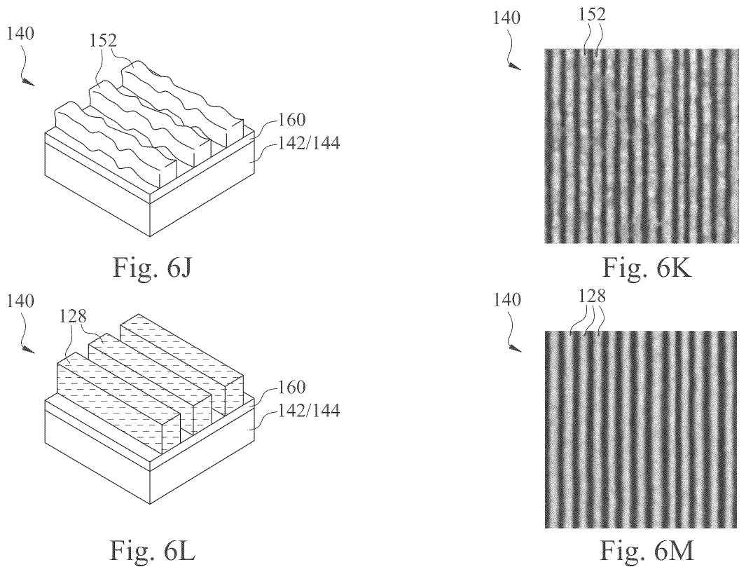

FIGS. 6A-6I are cross-sectional views of a wafer 140 at various stages of processing, in accordance with some embodiments. With reference to FIG. 6A, a wafer 140 includes a substrate 142 and a hard mask layer 144. The substrate 142 and the hard mask layer 144 can be substantially similar to the substrate 142 and the hard mask layer 144 of FIG. 5A. The process shown in relation to FIGS. 6A-6I utilizes directed self-assembly processes to form features on the substrate 142.

The wafer 140 includes a layer 160 on the hard mask layer 144. In some embodiments, the layer 160 includes an organic polymer. The organic polymer can include a photoresist. Alternatively, the layer 160 can include a dielectric material with a composition that can be changed by exposure to light. The layer 160 can have a thickness between 5 nm and 500 nm. Other thicknesses and materials can be utilized for the layer 160 without departing from the scope of the present disclosure.

A layer of photoresist 150 has been deposited on the layer 160. The layer of photoresist 150 can include a positive photoresist or a negative photoresist. In an example in which the layer 160 includes a photoresist, the photoresist 150 can be a different type of photoresist than the layer 160.

In FIG. 6B, a photolithography process has been performed on the layer of photoresist 150. In some embodiments, a photolithography process includes an extreme ultraviolet (EUV) photolithography process. In particular, the photoresist 150 is irradiated via a mask with EUV light and chemically changed portions of the layer of photoresist 150 have been removed to leave photoresist structures 152 in accordance with the mask pattern. Other types of photolithography processes can be performed without departing from the scope of the present disclosure. In some embodiments, the pitch of the photoresist structures 152 is between 20 nm and 50 nm, though other pitches can be utilized without departing from the scope of the present disclosure.

Though not apparent in the view of FIG. 6B, the EUV photolithography process may suffer some drawbacks with small pitches and low radiation doses. For example, a stochastic effect of the EUV radiation may cause uneven edges and surfaces in the photoresist structures 152 after patterning. These distortions may then be transferred to integrated circuit features, resulting in poorly functioning or non-functioning circuits. One possible remedy for this is to utilize directed self-assembly materials and processes to rectify patterns after photolithography processes. Advantageously, as will be set forth in more detail below, directed self-assembly processes with high boiling point solvents and rapid high temperature thermal annealing can rectify deformities in the photoresist patterns.

In FIG. 6C, and a radiation process is performed to irradiate the exposed portions 164 of the layer 160. The result is that the composition of the exposed portions 164 of the layer 160 is changed relative to the nonexposed portions 162. This can cause the exposed portions 164 to have a significantly different hydrophilic or hydrophobic property than the nonexposed portions 162.

In FIG. 6D, the photoresist structures 152 have been removed. Removal of the photoresist structures 152 can be accomplished with an etching process that selectively etches the photoresist structures 152 with respect to the layer exposed portions 164 and nonexposed portions 162 of the layer 160. Collectively, the exposed portions 164 and nonexposed portions 162 are a patterned structure above the substrate 142. The pattern of the patterned structure corresponds to the positions of the exposed portions 164 and nonexposed portions 162 of the layer 160.

In FIG. 6D, a directed self-assembly film 120 has been deposited on the patterned structure. In particular, the directed self-assembly film 120 has been deposited on the exposed portions 164 and nonexposed portions 162 of the layer 160. In the process shown in FIG. 6D, the directed self-assembly film includes a diblock copolymer material and a solvent. In other embodiments, the copolymer material can be a triblock copolymer material or other number of blocks. In one example, the diblock copolymer material includes PS-b-PMMA, though other copolymer materials can be utilized without departing from the scope of the present disclosure. The solvent is a high boiling point solvent, as described in relation to FIGS. 1-5R. The solvent can include one of the solvents shown in FIG. 4, or another suitable high boiling point solvent. The directed self-assembly film 120 can be deposited via a spin-on process, or via another process.

In some embodiments, the solvent is mixed with the copolymer material prior to depositing the directed self-assembly film 120 on the wafer 140. Alternatively, the copolymer material can be deposited on the wafer 140, followed by exposing the copolymer material to the solvent. Various processes for forming the directed self-assembly film 120 can be utilized without departing from the scope of the present disclosure.

In FIG. 6E, a rapid thermal annealing process is performed. The rapid thermal annealing process can be performed at a temperature between 200° C. and 350° C., as described previously in relation to FIG. 1. The rapid thermal annealing process can have a duration between 60 seconds and 300 seconds, as described previously in relation to FIG. 1. Other temperatures and durations can be utilized without departing from the scope of the present disclosure.

In FIG. 6E, first polymer structures 126 and second polymer structures 128 have been formed from the directed self-assembly film 120. In particular, performing the rapid high temperature annealing process with the high boiling point solvent has resulted in a well-ordered pattern of alternating stripes or blocks of the first polymer structures 126 and the second polymer structures 128. In some embodiments, the first polymer structures 126 are PMMA and the second polymer structures 128 are PS, though other polymer materials can be utilized without departing from the scope of the present disclosure.

The pattern of the first polymer structures 126 and second polymer structures 128 are based on the pattern of the exposed portions 164 and nonexposed portions 162 of layer 160. In particular, the polymer material of the second polymer structures 128 selectively assembles on the top surfaces of the nonexposed portions 162. This can be the result of the nonexposed portions 162 being more hydrophobic or more hydrophilic than the material exposed portions 164. The polymer material of the second polymer structures 128 selectively forms on the hydrophobic or hydrophilic nonexposed portions 162. The polymer material of the first polymer structures 126 forms adjacent to the second polymer structures 128 and has a similar width as the second polymer structures 128. The first polymer structures 126 are formed between the second polymer structures 128. The result is the alternating pattern of the first and second polymer structures as shown in FIG. 6B. The pitch of the second polymer structures 128 may be between 20 nm and 50 nm, though other pitches can be utilized without departing from the scope of the present disclosure.

Advantageously, the first polymer structures 126 and second polymer structures 128 form without the deformities of the photoresist structures 152. Accordingly, forming the first and second polymer structures 126 and 128 corresponds to a rectification process for the pattern of the photoresist structures 152. This enables smaller pitches that can be reliably formed with EUV photolithography alone.

In FIG. 6F, an etching process has been performed. The etching process selectively removes the first polymer structures 126 and the exposed portions 164 of the layer 160 with respect to the second polymer structures 128 and the hard mask layer 144. The effect is to form trenches 154 between the remaining polymer structures 128. Portions of the top surface of the hard mask layer 144 are exposed in the trenches 154. The second polymer structures 128 are not substantially etched.

In FIG. 6G, an etching process has been performed. The etching process selectively etches the material of the hard mask layer 144 with respect to the substrate 142. The result is that the trenches 154 extend through the hard mask layer 144 to the surface of the substrate 142.

In FIG. 6H, one or more etching processes have been performed to remove the second polymer structures 128, and the remaining portions of the nonexposed portions 162 of the layer 160. A conductive material 156 has been deposited on the exposed portions of the substrate 142 and the remaining portions of the hard mask layer 144. The conductive material 156 can be deposited by physical vapor deposition (PVD), chemical vapor deposition (CVD), atomic layer deposition (ALD), or by another deposition process. The conductive material 156 can include aluminum, copper, tungsten, titanium, gold, tantalum, or other conductive materials.

In FIG. 6I, a planarization process has been performed. The planarization process planarizes the top surface of the conductive material 156 with the top surface of the hard mask layer 144. The planarization process can include a chemical mechanical planarization (CMP) process, or another type of planarization process. The result is that metal lines 158 are formed on the substrate 142. The metal lines can correspond to conductive signal lines of an integrated circuit. The metal lines 158 can correspond to metal lines of a metal 0, metal 1, or metal interconnect layer of an integrated circuit. Alternatively, the process shown through FIG. 5K can be utilized to form conductive vias or plugs that can connect to other structures. The metal lines have a pitch based on the pitch of the first polymer structures 126.

In FIG. 6I, the hard mask layer 144 has been removed via an etching process. Subsequently, dielectric layers, such as an interlevel dielectric layer or other dielectric layers, can be formed on the substrate 142 covering the metal lines 158. In subsequent processes, conductive vias can be formed to contact the metal lines 158.

FIG. 6J is a perspective view of the wafer 140 at the stage of processing shown in FIG. 6B. In FIG. 6J, the distortions and deformities in the photoresist structures 152 are apparent. FIG. 6K is a top view of the wafer 140 at the stage of processing shown in FIG. 6B. The top view of FIG. 6K illustrates distortions and deformities in the photoresist structures 152.

FIG. 6L is a perspective view of the wafer 140 at the stage of processing corresponding to FIG. 6E, though the exposed portions 164 have not yet been removed. The perspective view of FIG. 6L illustrates how the second polymer structures 128 do not include the distortions and deformities from the photoresist structures 152. Accordingly, the directed self-assembly process has effectively rectified deformities associated with the EUV photolithography process. Furthermore, due to the use of the high boiling point solvent and the high temperature rapid thermal annealing process, the directed self-assembly process can be performed very quickly and effectively. FIG. 6M is a top view of the wafer 140 of FIG. 6L. FIG. 6M further illustrates that deformities of the photoresist structures 152 have been rectified by the second polymer structures 128.

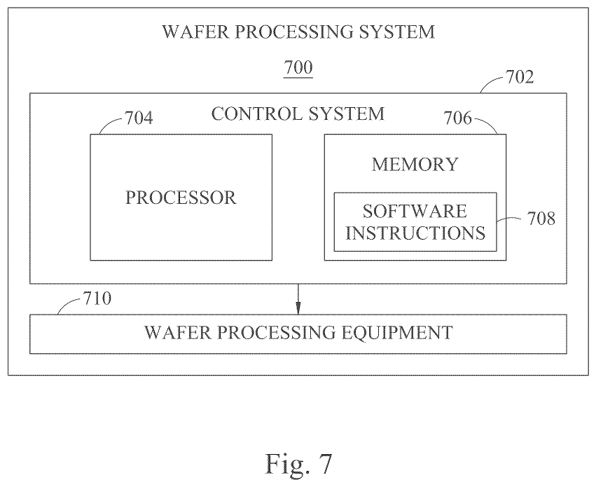

FIG. 7 is a block diagram of a wafer processing system 700, in accordance with some embodiments. The wafer processing system 700 can be utilized to perform the wafer processing procedures described in relation to FIGS. 1-6M. The wafer processing system includes a control system 702. The control system 702 includes one or more processors 704 and one or more memories 706. The one or more memories 706 store software instructions 708. The wafer processing system 700 includes wafer processing equipment 710.

The wafer processing equipment 710 can include wafer transfer systems, thin-film deposition systems, etching systems, spin-on coating systems, thermal annealing systems, chemical and material storage systems, photolithography systems, wafer storage systems, wafer inspection systems, wafer testing systems, ion implantation systems, and other types of systems and equipment. The wafer processing equipment 710 performs the physical wafer processing shown and described in relation to FIGS. 1-6M.

The software instructions 708, when executed by the processor 704, cause the control system 702 to control the wafer processing equipment 710 to perform the wafer processing procedure shown and described in relation to FIGS. 1-6M. The control system 702 can include a dispersed control system with processing and memory resources located at various locations within a wafer processing installation, at multiple wafer processing installations, and at locations separate from wafer processing installations. The control system 702 can include cloud-based processing and memory resources.

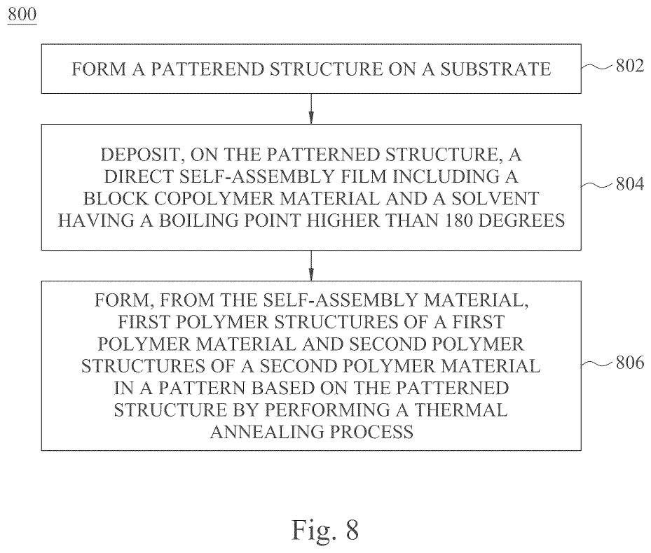

FIG. 8 is a flow diagram of a method 800 for forming features on a wafer, in accordance with some embodiments. The method 800 can utilize the processes, systems, and components described in relation to FIGS. 1-7. At 802, the method 800 includes forming, on a substrate, a patterned structure. One example of a substrate is the wafer 140 of FIG. 5A. One example of a patterned structure are layers 146 and 148 of FIG. 5F. At 804, the method 800 includes depositing, on the patterned structure, a directed self-assembly film including a block copolymer material and a solvent having a boiling point higher than 180 degrees. One example of a directed self-assembly film is the directed self-assembly film 120 of FIG. 5F. One example of a block copolymer material is the block copolymer material 122 of FIG. 2A. One example of a solvent is the solvent 124 of FIG. 2A. At 806, the method 800 includes forming, from the self-assembly material, first polymer structures of a first polymer material and second polymer structures of a second polymer material in a pattern based on the patterned structure by performing a thermal annealing process. One example of first polymer structures are the first polymer structures 126 of FIG. 5G. One example of second polymer structures are the second polymer structures 128 of FIG. 5G.

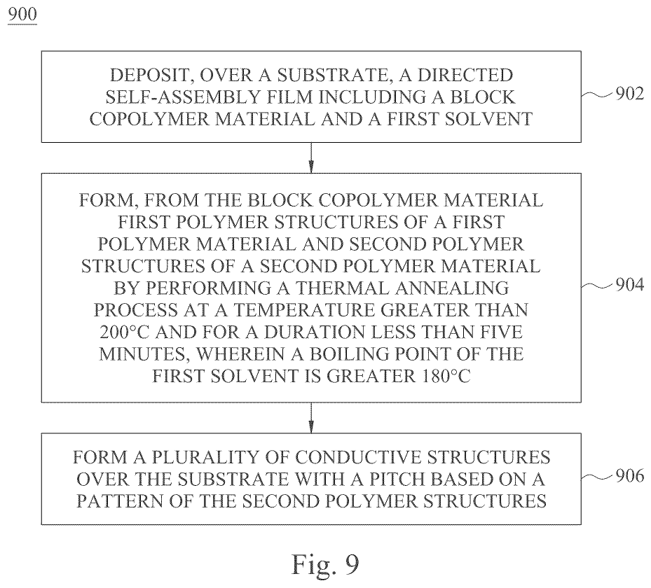

FIG. 9 is a flow diagram of a method 900 for forming features on a wafer, in accordance with some embodiments. The method 900 can utilize the processes, systems, and components described in relation to FIGS. 1-8. At 902, the method 900 includes depositing, over a substrate, a directed self-assembly film including a block copolymer material and a first solvent. One example of a substrate is the wafer 140 of FIG. 5A. One example of a directed self-assembly film is the directed self-assembly film 120 of FIG. 5F. One example of a block copolymer material is the block copolymer material 122 of FIG. 2A. One example of a first solvent is the solvent 124 of FIG. 2A. At 904, the method 900 includes forming, from the block copolymer material, first polymer structures of a first polymer material and second polymer structures of a second polymer material by performing a thermal annealing process at a temperature greater than 200° C. and for a duration less than five minutes, wherein a boiling point of the first solvent is greater 180° C. One example of first polymer structures are the first polymer structures 126 of FIG. 5G. One example of second polymer structures are the second polymer structures 128 of FIG. 5G. At 906, the method 900 includes forming a plurality of conductive structures over the substrate with a pitch based on a pattern of the second polymer structures. One example of conductive structures are the metal lines 158 of FIG. 5L.

Embodiments of the present disclosure utilize novel directed self-assembly processes to provide reliable feature formation in significantly reduced amounts of time. Embodiments of the present disclosure utilize block copolymers in conjunction with high boiling point solvents for rapid directed self-assembly processes. Because the directed self-assembly processes used high boiling point solvents, annealing processes can be performed at higher temperatures and for significantly reduced lengths of time while producing patterned morphologies from the block copolymers with very small pitches. The result is that small pitch feature patterns are formed effectively and efficiently. This further results in faster overall processing for semiconductor wafers, integrated circuits with higher performances, and better overall yields.

In some embodiments, a method includes forming, on a substrate, a patterned structure and depositing, on the patterned structure, a directed self-assembly film including a block copolymer material and a solvent having a boiling point higher than 180. The method includes forming, from the self-assembly material, first polymer structures of a first polymer material and second polymer structures of a second polymer material in a pattern based on the patterned structure by performing a thermal annealing process.

In some embodiments, a method includes depositing, over a substrate, a directed self-assembly film including a block copolymer material and a first solvent and forming, from the block copolymer material first polymer structures of a first polymer material and second polymer structures of a second polymer material by performing a thermal annealing process at a temperature greater than 200° C. and for a duration less than five minutes, wherein a boiling point of the first solvent is greater than 180° C. The method includes forming a plurality of conductive structures over the substrate with a pitch based on a pattern of the second polymer structures.

In some embodiments, a system includes at least one computer memory storing software instructions and at least one processor configured to execute the software instructions. Executing the software instructions causes a control system to perform a method. The method includes depositing, over a substrate, a directed self-assembly film including a block copolymer material and a solvent and forming, from the block copolymer material first polymer structures of a first polymer material and second polymer structures of a second polymer material by performing a thermal annealing process at a temperature greater than 200° C. for a duration less than five minutes, wherein a boiling point of the first solvent is greater than 180° C.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming, on a substrate, a patterned structure;
depositing, on the patterned structure, a directed self-assembly film including a block copolymer material and a solvent; and
forming, from the self-assembly film, first polymer structures of a first polymer material and second polymer structures of a second polymer material in a pattern based on the patterned structure by performing a thermal annealing process.

2. The method of claim 1, comprising performing the thermal annealing process with a temperature greater than 200° C., wherein the solvent has a boiling point higher than 180° C.

3. The method of claim 2, comprising performing the thermal annealing process for a duration less than five minutes.

4. The method of claim 1, wherein the solvent has a relative energy difference of less than 1 for the first polymer material and for the second polymer material.

5. The method of claim 1, wherein the solvent includes a first solvent and a second solvent each having a boiling point higher than 180° C.

6. The method of claim 5, wherein the first solvent has a relative energy difference less than one for the first polymer material, wherein the second solvent has a relative energy difference less than one for the second polymer material.

7. The method of claim 1, wherein the solvent has a boiling point higher than 240° C.

8. The method of claim 7, comprising performing the thermal annealing process at a temperature greater than 250° C. ° C.

9. The method of claim 1, comprising:
selectively removing the first polymer structures with respect to the second polymer structures; and
forming metal lines over the substrate having a pitch based on the second polymer structures.

10. The method of claim 1, comprising:
selectively removing the first polymer structures with respect to the second polymer structures;
forming a plurality of spacers in place of the removed first polymer structures; and
forming a plurality of metal lines over the substrate having a pitch based on the spacers.

11. A method, comprising:
depositing, over a substrate, a directed self-assembly film including a block copolymer material and a first solvent;
forming, from the block copolymer material, first polymer structures of a first polymer material and second polymer structures of a second polymer material by performing a thermal annealing process; and
forming a plurality of conductive structures over the substrate with a pitch based on a pattern of the second polymer structures.

12. The method of claim 11, comprising performing the thermal annealing process at a temperature greater than 200° C. and for a duration less than five minutes, wherein a boiling point of the first solvent is greater 180° C., wherein depositing the self-assembly film includes depositing the self-assembly film on a patterned structure on the substrate.

13. The method of claim 12, wherein the patterned structure includes an organic polymer.

14. The method of claim 12, comprising forming the patterned structure with an extreme ultraviolet photolithography process.

15. The method of claim 11, comprising selectively removing the first polymer structures with respect to the second polymer structures prior to forming the plurality of conductive structures.

16. The method of claim 11, wherein the first solvent includes one or more of tripropylene glycol monomethyl ether, 2-phenoxyethanol, heptyl ether, dodecane, N,N′-dimethylpropyleneurea, and 1,3-dimethyl-2-imidazolidinone.

17. The method of claim 11, wherein the self-assembly film includes PS-b-PMMA or PS-b-PDMS.

18. A system, comprising:
at least one computer memory storing software instructions; and
at least one processor configured to execute the software instructions, wherein executing the software instructions causes a control system to perform a method including:
depositing, over a substrate, a directed self-assembly film including a block copolymer material and a solvent; and
forming, from the block copolymer material, first polymer structures of a first polymer material and second polymer structures of a second polymer material by performing a thermal annealing process.

19. The system of claim 18, wherein the solvent has a relative energy difference less than one for the first polymer material and for the second polymer material.

20. The system of claim 18, wherein the method includes performing the thermal annealing process at a temperature greater than 200° C. for a duration less than five minutes, wherein a boiling point of the solvent is greater than 180° C.
